(19) United States
(12) Patent Application Publication
(10) Pub. No.: US 2015/0068793 A1
(43) Pub. Date: Mar. 12, 2015

(54) PRINTED CIRCUIT BOARD AND METHOD OF MANUFACTURING THE SAME

(71) Applicant: Samsung Electro-Mechanics Co., Ltd., Suwon (KR)

(72) Inventors: Myung Sam Kang, Hwasung (KR); Ki Hwan Kim, Yongin (KR)

(73) Assignee: Samsung Electro-Mechanics Co., Ltd., Suwon (KR)

(21) Appl. No.: 14/158,101

(22) Filed: Jan. 17, 2014

(30) Foreign Application Priority Data
Sep. 12, 2013 (KR) 10-2013-0109885

(51) Int. Cl. H05K 1/02; H05K 3/02; H05K 3/46

(52) U.S. Cl. CPC H05K 1/0271; H05K 3/4685; H05K 3/02
USPC 174/258; 29/852

(57) ABSTRACT

Disclosed herein are a printed circuit board and a method of manufacturing the same. The printed circuit board includes: an insulation layer; pattern parts formed on both surfaces of the insulation layer; a connection pad disposed between the pattern parts and having a step part; a first plated layer formed on the pattern part; an oxide film formed on a region excluding a region on which the first plated layer is formed; a second plated layer formed on the connection pad; and a solder ball covering the connection pad.

### CROSS REFERENCE(S) TO RELATED APPLICATIONS

This application claims the foreign priority benefit under 35 U.S.C. Section 119 of Korean Application No. 10-2013-0109685, entitled “Printed Circuit Board and Method of Manufacturing the Same” filed on Sep. 12, 2013, which is hereby incorporated by reference in its entirety into this application.

### BACKGROUND OF THE INVENTION

1. Technical Field

The present invention relates to a printed circuit board and a method of manufacturing the same, and more particularly, to a printed circuit board capable of improving adhesive reliability of a solder ball simplifying the number of manufacturing processes and a method of manufacturing the same.

2. Description of the Related Art

In accordance with a rapid development of an electronic industry recently, since electronic components are highly integrated and have high performance, and the electronic components such as an integrated chip (IC), a central processing unit (CPU), a variety of elements, and the like are mounted, a printed circuit board which is used so as to be electrically connected to a main board is also multi-functionalized and a package using the printed circuit board is also miniaturized.

Particularly, in a case of a memory package, a plurality of electronic components may be laminated and installed in order to increase capacity of the package, and a thickness of the package has also become thin, as a total of thickness of a mobile device having the package mounted therein is gradually thinned.

The memory package as mentioned above is mainly manufactured in a form of package of package (POP) in which the package is laminated on the package, and since an upper package is mounted on a lower package, warpage variation of the package should be small.

### RELATED ART DOCUMENT

### Patent Document

(Patent Document 1) Korean Patent Laid-Open Publication No. 2009-0042569

### SUMMARY OF THE INVENTION

An object of the present invention is to provide a printed circuit board capable of excluding a solder resist from components controlling warpage of the printed circuit board and preventing adhesion of a solder ball from being weaken, which may be caused by the exclusion of the solder resist, and a method of manufacturing the same.

According to an exemplary embodiment of the present invention, there is provided a printed circuit board, including: an insulation layer; pattern parts formed on both surfaces of the insulation layer; a connection pad formed on the same layer as the pattern part and having a step part; a first plated layer formed on the pattern part; an oxide film formed on a region excluding a region on which the first plated layer is formed; a second plated layer formed on the connection pad; and a solder ball covering the connection pad.

The insulation layer may be provided with a through-hole, and the through-hole may be filled with an interlayer plated layer to electrically connect the pattern parts to each other.

The connection pad may be formed to be protruded in a bump form between the pattern parts provided on a lower surface of the insulation layer, and may have the step part formed on a peripheral part to thereby form resistibility against cross section stress of the solder ball by the step part.

The oxide film may be formed by a brown oxide, a black oxide or an OSP process which is an organic surface protective agent.

According to another exemplary embodiment of the present invention, there is provided a method of manufacturing a printed circuit board, the method including: preparing a base substrate; forming a through-hole in the base substrate; forming first dry film resist patterns on both surfaces of the base substrate so that plating pattern forming position is opened; forming pattern parts and a connection pad by growing a plated layer on opened regions of the first dry film resist pattern; forming a second dry film resist pattern on the pattern parts; forming a first plated layer and a second plated layer on opened regions of the second dry film resist pattern; removing the second dry film resist pattern; and forming an oxide film on a region excluding a region on which the first plated layer of the pattern part is formed.

### BRIEF DESCRIPTION OF THE DRAWINGS

FIGS. 1 to 9 are process views showing a method of manufacturing a printed circuit board according to an exemplary embodiment of the present invention;

FIG. 1 is a cross-sectional view of a base substrate;

FIG. 2 is a cross-sectional view of a state in which a through-hole is formed in the base substrate;

FIG. 3 is a cross-sectional view of a state in which a first dry film resist pattern is formed in the base substrate having the through-hole formed therein;

FIG. 4 is a cross-sectional view of a state in which a plating process is performed for an opened region of the first dry film resist pattern;

FIG. 5 is a cross-sectional view of a state in which a second dry film resist pattern is formed on a pattern part;

FIG. 6 is a cross-sectional view of a state in which a Ni/Au plated layer is formed on the opened region of the second dry film resist pattern;

FIG. 7 is a cross-sectional view of a state in which the second dry film resist pattern is removed;

FIG. 8 is a cross-sectional view of a state in which an oxide film is formed on the pattern part; and

FIG. 9 is a cross-sectional view of the printed circuit board according to the exemplary embodiment of the present invention of a state in which a solder ball is coupled to a connection pad of a lower surface.

### DESCRIPTION OF THE PREFERRED EMBODIMENTS

The acting effects and technical configuration with respect to the objects of a printed circuit board and a method of manufacturing the same according to the present invention will be clearly understood by the following description in which exemplary embodiments of the present invention are described with reference to the accompanying drawings.

First, FIG. 9 is a cross-sectional view of a printed circuit board according to an exemplary embodiment of the present invention.

As shown, the printed circuit board 100 according to the exemplary embodiment of the present invention may be configured to include an insulation layer 110, pattern parts 120 formed on both surfaces of the insulation layer 110, and a connection pad 130 formed on the same layer as the pattern part 120. In this case, in FIG. 9, the connection pad 130 may be disposed between the pattern parts 120 throughout the printed circuit board 100 in a state in which a portion of the printed circuit board 100 is cut.

In this case, the pattern part 120 may have an oxide film 121 formed on a surface thereof and the connection pad 130 formed on the insulation layer 110 and between the pattern parts 120 may have a Ni/Au plated layer 132 formed on a surface thereon. In addition, the connection pad 130 is configured in a bump form in which the step part 131 is formed, and a solder ball 140 may be coupled to the connection pad 130 so as to cover the connection pad 130. In this case, the solder ball 140 may have improved adhesive reliability by the connection pad 130 and the step part 131.

The insulation layer 110 may serve as a core of the printed circuit board according to the exemplary embodiment of the present invention and may be configured of an insulating material of a resin or an ABF material. In addition, a glass woven material such as a glass cross or a glass fabric is impregnated in the resin, such that the insulation layer 110 may be assigned with rigidity and may have resistibility against warpage caused by heat and pressure during a manufacturing process of the board.

In addition, the insulation layer 110 may have a via or a through-hole 111 formed therein. The through-hole 111 may be formed to penetrate through the insulation layer 110 by a mechanical drilling process or laser process and may have an inter-layer plated layer 123 filled therein to be used as a connection unit electrically connecting between upper and lower portions of the insulation layer 110.

The pattern part 120 and the connection pad 130 may be formed on the insulation layer 110. The pattern part 120 and the connection pad 130 are formed by performing a plating process on the insulation layer 110. More specifically, a seed layer (not shown) is first formed and a plated layer is grown on the seed layer by performing an electroplating or electroless plating, such that the pattern part 120 and the connection pad 130 may be formed. In this case, the connection pad 130 may be simultaneously formed on an upper surface and a lower surface of the insulation layer 110, or may be protruded from any one surface of the upper surface or the lower surface in a bump form. In addition, the connection pad 130 may be formed to have the same height as the pattern part 120 or the height less than the pattern part 120 in a space between the pattern parts 120.

In addition, the connection pad 130 may have the step part 131 having a form in which a central portion thereof is protruded. The step part 131 is formed by growing the plated layer on the above-mentioned seed layer. The step part 131 may be formed by having a width of the seed layer greater than that of the plated layer by not removing a portion of the seed layer surrounding the plated layer at the time of removing the seed layer.

In addition, the connection pad 130 may further have a second plated layer 132 formed on the upper surface including the step part 131. The second plated layer 132 may be configured of a Ni/Au plated layer and adhesive performance of the solder ball 140 may be improved by the second plated layer 132, where a rough layer is generated by an intermetallic compound (IMC) generated while nickel is oxidized at the second plated layer 132 formed at an adhesive interface between the solder ball 140 and the connection pad 130 at the time of reflow process for adhesion of the solder ball, that is, the second plated layer 132 by the Ni/Au plating process, the adhesion between the surface of the connection pad 130 and the second plated layer 132 may be improved.

Meanwhile, the pattern part 120 may be formed to have the same height as the connection pad 130 and may have an oxide film 121 formed on a surface thereof. The oxide film 121 functions as the insulation layer in place of a solder resist layer formed on the pattern part and may serve to protect the pattern part from the outside. In addition, the pattern part 120 formed by performing the plating on the seed layer is formed by a copper (Cu) plating, the oxide film 121 may be formed by performing a brown oxide, a black oxide or an OSP process which is an organic surface protective agent on the surface of the pattern part 120.

In addition, the first plated layer 122 may be formed on a portion in which the oxide film 121 is not applied on the pattern part 120. The first plated layer 122 may function as a pad or pattern electrically connected to the via or the like which may be formed in the insulation layer formed on the pattern part 120 and built-up on the pattern part 120.

The printed circuit board 100 according to the exemplary embodiment of the present invention having the above-mentioned configuration may decrease a thickness of the printed circuit board since the solder resist layer needs not to be separately configured, due to the oxide film 121 formed on the pattern part 120 serving as the solder resist, and may decrease warpage occurrence since the solder resist layer in which warpage is mainly generated by heat and pressure at the time of manufacturing the printed circuit board is removed.

A method of manufacturing the printed circuit board according to the exemplary embodiment of the present invention having the above-mentioned configuration will be described with reference to the following drawings in which the manufacturing processes are sequentially shown.

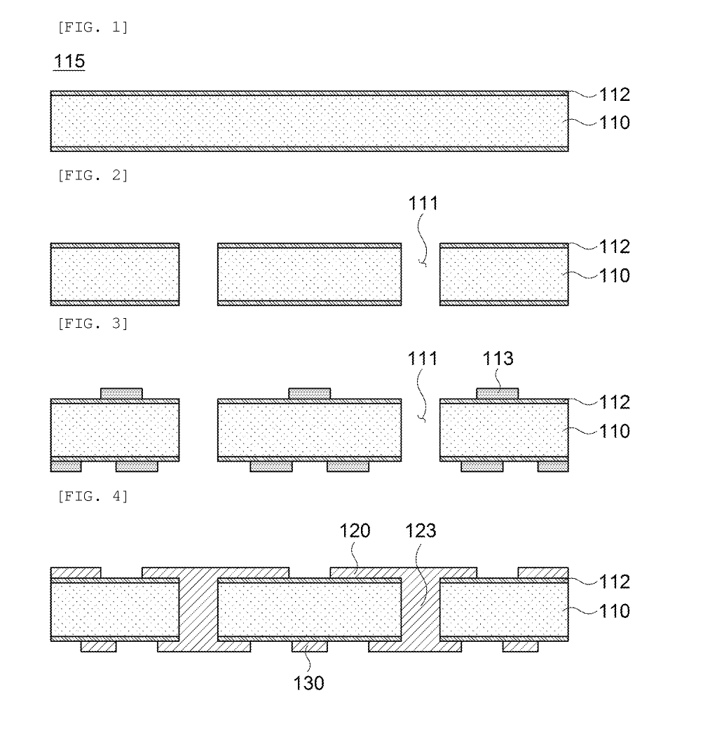

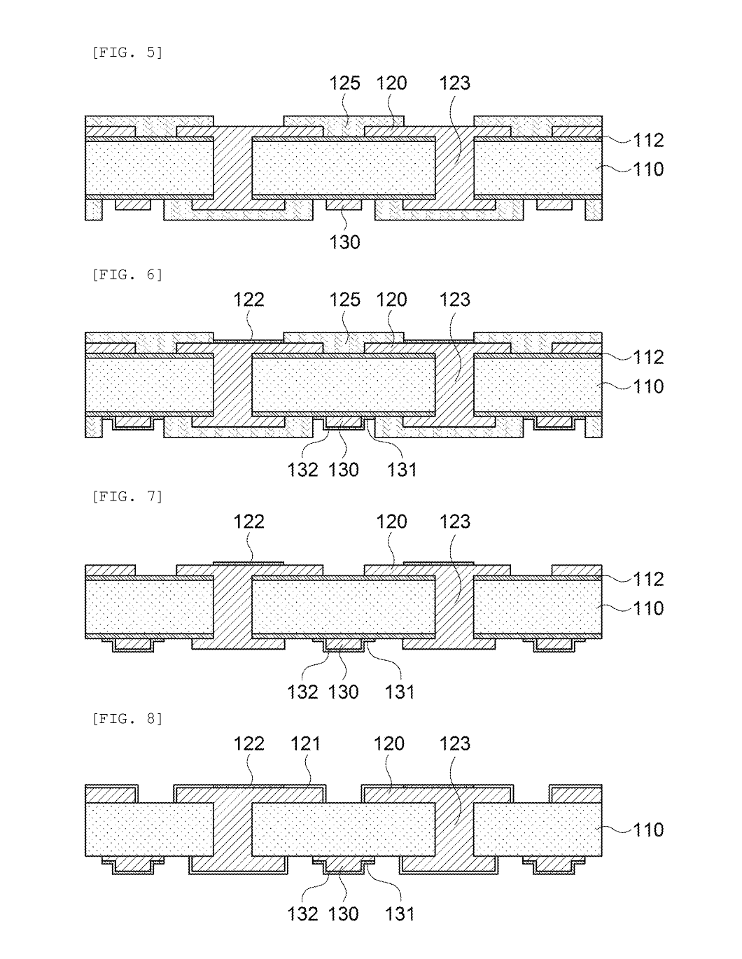

FIGS. 1 to 9 are process views showing a method of manufacturing a printed circuit board according to an exemplary embodiment of the present invention, FIG. 1 is a cross-sectional view of a base substrate, FIG. 2 is a cross-sectional view of a state in which a through-hole is formed in the base substrate, FIG. 3 is a cross-sectional view of a state in which a first dry film resist pattern is formed in the base substrate having the through-hole formed therein, and FIG. 4 is a cross-sectional view of a state in which a plating process is performed for an opened region of the first dry film resist pattern.

As shown, the printed circuit board first prepares the base substrate. As the base substrate 115, a copper clad laminate (CCL) having copper layers 112 formed on both surfaces thereof may be used, and the copper layer 112 having a thickness of several gm or less may be separately formed on both surfaces of the insulation layer 110 to thereby configure the copper clad laminate. The base substrate 115 having the copper layer 112 formed thereon may have the through-hole 111 formed therein as shown in FIG. 2. The through-hole 111 may be processed by the mechanical drilling process or laser process and may be formed by forming the via holes in upper and lower portions of the base substrate. In addition, after forming the via hole, the through-hole 111 may form an inner wall surface thereof to be flat by performing a flattening process for an inclined wall surface using desmear chemicals such as sodium permanganate, or the like.

After the through-hole 111 is formed in the base substrate 115, a photosensitive film or photosensitive resin is applied on the base substrate 115 and the photosensitive film is exposed and developed, such that a first dry film resist pattern 113 having an opened pattern forming position may be formed.

An outer region of the first dry film resist pattern 113 is a position at which the pattern part 120 will be formed and may be provided with the pattern part 120 by growing the plated layer by an electroplating or electroless plating process using the copper layer 112 as the seed layer. In this case, the pattern part 120 may simultaneously perform a copper plating process for the outer region of the first dry film resist pattern 113 and an inner portion of the through-hole 111 to thereby electrically connect the upper and lower portions of the base substrate 115. In addition, the lower surface of the base substrate 115 may be provided with the connection pad 130 by growing the plated layer between the pattern parts 120.

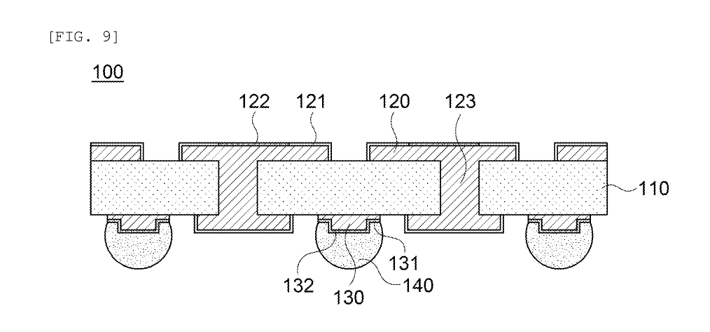

Next, FIG. 5 is a cross-sectional view of a state in which a second dry film resist pattern is formed on a pattern part, FIG. 6 is a cross-sectional view of a state in which a Ni/Au plated layer is formed on the opened region of the second dry film resist pattern, and FIG. 7 is a cross-sectional view of a state in which the second dry film resist pattern is removed.

As shown in FIGS. 5 to 7, the photosensitive film or photosensitive resin is applied on both surface of the base substrate 115 having the pattern part 120 formed thereon and the photosensitive film or photosensitive resin is exposed and developed, such that a second dry film resist pattern 125 having an opened plated layer 122 forming position may be formed. In this case, the second dry film resist pattern 125 formed on the lower surface of the base substrate 115 may form an open region so that the copper layer 112 surrounding the connection pad 130 is exposed by a predetermined portion. The open region of the second dry film resist pattern 125 on the lower surface of the printed circuit board as described above forms a solder ball connection region.

The open region of the second dry film resist pattern 125 may be provided with a first plated layer 122 formed by the Ni/Au plating process by performing the electroplating. In this case, a second plated layer 132 formed by the Ni/Au plating process may also be formed on the connection pad 130 formed on the lower surface of the printed circuit board and the copper layer 112 surrounding thereof.

Next, when the electroplating process for forming the Ni/Au plated layers 122 and 132 in the opened region of the second dry film resist pattern 125 is completed, the second dry film resist pattern 125 is removed, such that the pattern part 120, the plated layers 122 and 132 plated on the pattern part 120 and the connection pad 130, and the copper layer 112 between the pattern parts 120 may be exposed.

Next, FIG. 8 is a cross-sectional view of a state in which an oxide film is formed on the pattern part and FIG. 9 is a cross-sectional view of the printed circuit board according to the exemplary embodiment of the present invention of a state in which a solder ball is coupled to a connection pad of a lower surface.

As shown, when the second dry film resist pattern 125 is removed, the copper layer 112 used as the seed layer for forming the pattern part 120 may be removed by etching. As portions in which the copper layer 112 is removed, the copper layer 112 in the region between the pattern parts 120, and the region between the pattern part 120 and the connection pad 130 having the second plated layer 132 formed thereon is removed, such that the insulation layer 110 used as the base substrate is exposed and electrical short of the pattern part 120 may be made.

Next, an oxide film 121 may be formed to have a thickness below several μm at regions on the pattern part 120 excluding the region in which the first plated layer 122 is formed. The oxide film 121 may be formed by the brown oxide, the black oxide or the OSP process on the pattern part 120 made of the copper plated layer and may be configured as a final insulation layer on the pattern part 120 which is exposed to the outside. In this case, the pattern part 120 formed on the insulation layer 110 may form a single copper plated layer by integrating the copper layer 112 and the plated layer grown on the copper layer 112 at the same time as the formation of the oxide film 121. Similarly, the connection pad 130 may also be formed in a pattern having the same height as the pattern part 120 by integrating the plated layer grown on the copper layer 112, and the un-removed copper layer 112 around the connection pad 130 is configured in a land form, such that the connection pad 130 having the step part 131 may be configured. In this case, the second plated layer 132 formed by the Ni/Au plating process may be formed only on the upper surface of the connection pad 130 having the step part 131.

Next, the solder ball 140 may be coupled onto the connection pad 130 formed on the lower surface of the printed circuit board. The solder ball 140 is formed on the connection pad 130 and is covered so as to include the step part 131, such that when external force is applied from the side portion of the solder ball 140, resistibility against cross-section stress of the solder ball 140 may be secured by the step part 131 formed on the connection pad 130, thereby making it possible to improve adhesive reliability between the solder ball 140 and the connection pad 130.

Meanwhile, the printed circuit board according to the exemplary embodiment of the present invention may form the plated layer without having a separate plating lead line for performing the Ni/Au plating process at the time of forming the second plated layer 132 by the Ni/Au plating process on the pattern layer 120 and the connection pad 130 based on FIG. 6. Therefore, noise occurrence in the printed circuit board caused by the plating lead line may be prevented.

According to the exemplary embodiment of the present invention, the printed circuit board and the method of manufacturing the same may decrease the thickness of the printed circuit board since the solder resist layer needs not to be separately configured, due to the oxide film formed on the pattern part serving as the solder resist, and may decrease warpage occurrence since the solder resist layer in which warpage is mainly generated by heat and pressure at the time of manufacturing the printed circuit board is removed.

In addition, since the solder ball is covered to include the step part of the connection pad, when external force is applied from the side portion of the solder ball, resistibility against cross-section stress of the solder ball may be secured by the step part, thereby making it possible to improve adhesive reliability of the solder ball.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A printed circuit board, comprising:
an insulation layer;
pattern parts formed on both surfaces of the insulation layer;
a connection pad formed on the same layer as the pattern part and having a step part;
a first plated layer formed on the pattern part;
an oxide film formed on a region excluding a region on which the first plated layer is formed;
a second plated layer formed on the connection pad; and
a solder ball covering the connection pad.

2. The printed circuit board according to claim 1, wherein the insulation layer is provided with a through-hole, the through-hole being filled with an interlayer plated layer to electrically connect the pattern parts to each other.

3. The printed circuit board according to claim 1, wherein the connection pad is formed to be protruded in a bump form between the pattern parts provided on a lower surface of the insulation layer.

4. The printed circuit board according to claim 3, wherein the connection pad has the step part formed on a peripheral part thereof to thereby have a central part formed to be protruded and has resistibility against cross-section stress of the solder ball.

5. The printed circuit board according to claim 1, wherein the first plated layer and the second plated layer are formed by a Ni/Au plating process.

6. The printed circuit board according to claim 1, wherein the oxide film is formed by a brown oxide, a black oxide or an OSP process which is an organic surface protective agent.

7. A method of manufacturing a printed circuit board, the method comprising:
preparing a base substrate;
forming a through-hole in the base substrate;
forming first dry film resist patterns on both surfaces of the base substrate so that plating pattern forming position is opened;
forming pattern parts and a connection pad by growing a plated layer on opened regions of the first dry film resist pattern;
forming a second dry film resist pattern on the pattern parts;
forming a first plated layer and a second plated layer on opened regions of the second dry film resist pattern;
removing the second dry film resist pattern; and
forming an oxide film on a region excluding a region on which the first plated layer of the pattern part is formed.

8. The method according to claim 7, wherein the base substrate is configured by a copper clad laminate (CCL) having copper layers formed on both surfaces of an insulation layer.

9. The method according to claim 8, wherein the copper layer provided in the copper clad laminate is used as a seed layer in the forming of the pattern parts and the connection pad by growing the plated layer.

10. The method according to claim 8, wherein in the forming of the second dry film resist pattern, an opened region surrounding the connection pad among the opened regions of the second dry film resist pattern is formed so that a portion of the copper layer is exposed.

11. The method according to claim 7, wherein the first plated layer and the second plated layer are each formed on the connection pad together with a portion of the pattern parts.

12. The method according to claim 11, wherein the first plated layer and the second plated layer are formed by a Ni/Au plating process.

13. The method according to claim 9, further comprising, after the removing of the second dry film resist pattern, electrically shorting the pattern parts by removing the copper layer by etching.

14. The method according to claim 7, wherein in the forming of the oxide film on the pattern part, the oxide film is formed by a brown oxide, a black oxide or an OSP process.

15. The method according to claim 7, further comprising, after the forming of the oxide film on the pattern part, coupling a solder ball onto the connection pad.
